(19) United States
(12) Patent Application Publication
(10) Pub. No.: US 2007/0169917 A1
(43) Pub. Date: Jul. 26, 2007

(54) SYSTEM AND METHOD FOR MAINTAINING HEAT EXCHANGER OF LNG RECEIVING TERMINAL

(75) Inventor: William M. Bishop, Katy, TX (US)

Correspondence Address: BLACKWELL SANDERS PEPER MARTIN LLP, 720 OLIVE STREET, SUITE 2400, ST. LOUIS, MO, 63101, US

(73) Assignee: CONVERSION GAS IMPORTS, L.P., Houston, TX (US)

(21) Appl. No.: 11/307,061

(22) Filed: Jan. 20, 2006

(51) Int. Cl. H05K 7/20

(52) U.S. Cl. 165/80.4; 165/104.33; 361/700; 257/715

(57) ABSTRACT

A system and method for minimizing the environmental impact of water handling equipment such as heat exchangers and water handling systems, as for example those located at an LNG receiving facility. The system and method utilizes a low-speed pump impeller to flow the warmant through the annulus of the heat exchanger to minimize biota destruction caused by the pump impellers. Further, the system and method places the water intake pipes at levels in the source or reservoir for the water where biota concentration is at a minimum such that biota flowing through the annulus is minimized. No biocide, scale or corrosion inhibitors are injected during normal operation. The system or a portion of the system is shut down periodically to allow injection to a flush fluid containing biocide, scale inhibiters, and/or corrosion inhibitors. The flush is then drained and recovered.

### BACKGROUND OF INVENTION

1. Field of the Invention

This invention relates generally to heat exchangers using an aqueous coolant or warmant and to aqueous transmission systems in general, which may be subject to fouling, scaling or corrosion, and more particularly to liquefied natural gas (LNG) heat exchangers subject to these types of obstructions of said heat exchanger.

2. Background Art

In the natural gas industry, there is a procedure for transporting Liquefied Natural Gas (LNG) from stranded natural gas production sources to storage facilities. The natural gas is transported as LNG via a transport ship to a receiving terminal. At the LNG receiving terminal, the LNG is transferred from the transport ship and stored in cryogenic tanks or other storage means located on shore. At some later point in time, the LNG is then typically transferred from the storage tank to a conventional vaporizer system or other appropriate system and gasified for being transported to market via a pipeline network.

This means of transporting LNG is very important to the natural gas industry because these stranded gas sources are not located proximate a pipeline network for delivering the product to market. Therefore, LNG transport ships are utilized to transfer the natural gas from the stranded location to remotely located storage facilities that are proximate a pipeline network capable of delivering the natural gas to market.

There are various transport ships in service worldwide which are specifically designed to transfer or transport LNG as a cryogenic liquid at a temperature at or below minus 250 degrees Fahrenheit. The LNG is also transferred near or slightly above atmospheric pressure. A typical transport ship has a capacity to hold about three billion cubic feet of gas or approximately 840,000 barrels. The LNG receiving facilities typically include off-loading pumps and equipment for transferring LNG to cryogenic storage tanks or other appropriate storage means.

LNG receiving terminals are typically designed for peak shaving or as a base load facility. Base load LNG vaporization is the term applied to a system that requires almost constant vaporization of LNG for the base-load rather than periodic vaporization for seasonal or peak incremental requirements for a natural gas distribution system. An LNG transport ship will typically arrive every 3 to 5 days at a typical base load LNG facility. Therefore, the LNG off load cycle typically occurs every 3 to 5 days. The LNG can be pumped from the ship to the LNG storage tanks as a liquid at a temperature of approximately minus 250 degrees Fahrenheit. The LNG can be stored as a liquid at a low pressure of about 1 atmosphere. The off-load process typically takes about twelve hours.

Conventional base load LNG receiving terminals are continuously vaporizing the LNG from the cryogenic tanks and pumping gas into the pipeline for transport to the market. Therefore, during the time period between incoming transport ships, the LNG receiving facility continuously empties the cryogenic tanks by outputting gas into the pipeline network. This continuous emptying of the tanks will allow for off load of future LNG transport ships arriving in the future.

Industry has found that LNG cryogenic storage tanks are expensive to build and maintain. Further, the cryogenic tanks are on the surface and present a safety issue or may provide a possible target for a terrorist attempt. Industry has therefore developed various other methods to receive and store the LNG both for base load and peak shaving facilities. Industry has developed various ways to store LNG without the need of cryogenic tanks including the utilization of salt formations for salt cavern storage.

There are two difference conventional techniques utilized in salt cavern storage and they are compensated and uncompensated cavern storage. In a compensated cavern, brine our water is pumped into the bottom of the salt cavern to displace the hydrocarbon or other product out of the cavern. When the product is injected into the cavern, the brine is forced out. In an uncompensated storage cavern, no displacing liquid is utilized. Uncompensated caverns are commonly utilized to store natural gas that has been produced from wells. Therefore, the LNG receiving facility is equipped to take the LNG from the tanker, and vaporize it and then store the resulting gas in a salt cavern. However, uncompensated salt caverns for natural gas storage preferably operate in a temperature range of approximately plus 40 degrees Fahrenheit to 140 degrees Fahrenheit and pressures of 1,500 to 4,000 psig. If a cryogenic fluid at sub-zero temperatures is pumped into a cavern, thermo fracturing of the salt may occur and degrade the integrity of the salt cavern. For this reason, LNG at very low temperatures cannot be stored in a conventional salt cavern.

High pressure pumping systems combined with heat exchanger systems can be utilized to transfer LNG from the ship to a non-cryogenic storage means such as a salt cavern. A high pressure pump system can be utilized to raise the pressure of the LNG from about 1 atmosphere to about 1200 psig or more. This increased pressure changes the state of LNG from a cryogenic liquid to a dense phase natural gas (DPNG). The DPNG is pumped through a heat exchanger to raise the DPNG from about minus 250 degrees Fahrenheit to about 40 degrees Fahrenheit so that the DPNG can be stored in uncompensated salt caverns. U.S. Pat. Nos. 5,511,905 and 6,739,140 issued to William M. Bishop discloses this process.

The heat exchanger can be formed from one section of piping or multiple sections. The number of sections utilized in the heat exchanger depends on the special configuration and the overall footprint of the facility where the heat exchanger is installed. The number of sections also depends on the temperature of the fluid being warmed as well as the temperature of the warmant or the fluid utilized to raise the temperature of the DPNG. The heat exchanger can comprise coaxial pipes or conduits having an annulus space between the inner pipe and the outer pipe. The DPNG flows through the inner pipe and the warmant fluid flows through the annulus between the inner pipe and the outer shell pipe. The warmant that is utilized can be fresh water or sea water. The inner pipe of the heat exchanger must be cryogenically compatible. Therefore, the inner cryogenically compatible pipe can be made of high nickel steel which is compatible with the low temperature application. The interior cryogenically compatible pipe or conduit is positioned at or near the center of the outer pipe or outer conduit and is positioned by a plurality of centralizers thereby forming a uniform annulus there between. The warmant flows through the annulus area of the heat exchanger where the annulus is defined by the outside diameter of the inner cryogenically compatible pipe and the inner diameter of the outer conduit.

Piping can be utilized to connect a reservoir of salt water (or other warmant) with a low pressure pump with ports to allow fluid communication between the reservoir and the heat exchanger. The pump impellers cause the warmant to flow through the annulus of the heat exchanger to thereby raise the temperature of the DPNG. Therefore the cryogenic liquid enters the heat exchanger as a cold cryogenic liquid and leaves the outlet of the heat exchanger as a warm dense phase fluid.

It is important to avoid any blockage in the annulus of the heat exchanger which would hinder in any way the flow of the warmant thereby rendering the heat exchanger inoperable. Therefore, the flow rates and pipe diameter ratios must be properly determined to avoid any freezing in the annulus which would restrict flow of the warmant. Too narrow an annulus makes the warmant pressure drop too high, and too wide of an annulus slows the flow near the cryo wall and thus reduces the heat transfer. Optimum for a specific combination of fluids must be determined numerically or by experiment.

Therefore, it is apparent that the flow rate must be maintained in order to assure that a freeze up does not occur in the annulus. Therefore, any other blockages in the annulus must be avoided. Also, when utilizing salt water or other water, there is concern that a biofilm buildup can form on the inner diameter and outer diameter surfaces of the annulus thereby restricting a warmant flow. Various bacteria or micro organisms can exist in salt water and/or fresh water which can result in the forming of a biofilm within the annulus. Such biofilm buildup can restrict flow over time. Standard heat exchangers address the biofilm problem by constant injection of a biocide, which kills a large percent of the entrained biota as well as additional kills when the biocide is ejected into the source body of water.

Further, salt water or fresh water may have the tendency to have a corrosive effect within the annulus as well as causing a scale to form on the inner surfaces of the annulus. Therefore, it is clear that the utilization of sea water or fresh water as a warmant can cause various problems that ultimately restrict the flow of the warmant thereby inducing freeze up. Therefore, a method is needed to reduce or eliminate biofilm and scale and corrosion within the annulus. Use of brine as a warmant may also cause scaling.

Also, there can be negative effects on the ecology of a water reservoir when utilizing such heat exchangers. For example, when utilizing the high speed pumps, the impellers can sometimes destroy micro organisms in the sea water which is beneficial to the eco system of the reservoir or source of the sea water. After cycling of the warmant the micro organism population can be significantly depleted. Also, various methods for eliminating biofilm can also be detrimental to the eco system of the reservoir or source of the sea water. The same effect occurs where the micro organism population is significantly depleted. Also, filtration systems of many heat exchangers can destroy micro organisms. The filter screen openings many times do not have sufficient diameter to allow micro organisms to pass through the filter unharmed. A remedy is needed. Also, most heat exchangers are not designed for drainage or flushing or to allow for drying of the heat exchanger Therefore, a method is needed that not only resolves the biofilm issue but also is not detrimental to the overall eco system of the sea water or the source of the sea water.

### BRIEF SUMMARY OF INVENTION

The present invention is a system and method for minimizing the environmental impact of water treatment procedures utilized to treat water handling equipment such as heat exchangers located at an LNG receiving facility, and is further a treatment process utilized to control biofilm, scaling and corrosion. The system and method utilizes a low-speed pump impeller to flow the warmant through the annulus of the heat exchanger to minimize biota or micro organism destruction caused by the pump impellers. The low-speed pump impellers maintain low water speeds internal to the equipment to minimize destruction of biota during the process. Further, the system and method places the water intake pipes at levels in the source or reservoir for the sea water where biota concentration is at a minimum such that biota flowing through the annulus is minimized. This reduces destruction of biota as well as reduces the formation of biofilm. Also, the system includes a filter screen on the inlet of the exchanger that has an opening size large enough such that biota without self propulsion will most likely survive as the warmant passes through the filter. Others will be able to avoid the screen. This relatively large size of biota can be tolerated in the exchanger as the velocity is high enough so as to minimize settling in the system. In addition, the intake of a larger amount of biota, which minimizes kill at the screen, is acceptable past the screen as the system is biota friendly. The system is also designed such that the heat exchanger can quickly drain for drying. This will reduce the possibility of biofilm formation.

The system and method also utilizes a periodic flush and recover process for flushing out the annulus thereby reducing the formation of biofilm, scaling and corrosion. The periodic flushing of the annulus of the heat exchanger would occur during the downtime of the heat exchanger in between the times that LNG is being offloaded from incoming ships. This downtime can also be obtained by having an extra exchanger, thus allowing sequential shutdown of individual exchangers. The flush material utilized to flush the annulus would contain biocide to eliminate the possibility of forming biofilm as well as inhibitors to scaling and corrosion. Subsequent to flushing, the annulus of the heat exchanger can be allowed time to dry thereby further reducing the possibility of biofilm, scaling or corrosion.

Further, the heat exchanger conduits can be designed for easy drainage such that the recover and dry process occurs rapidly. The drainage should be designed such that the annulus is allowed to dry during the time between receiving the next incoming transport ship. Forced air can also be used as a drying agent if this is deemed useful. Also, the present invention provides a heat exchanger warmant filtration system where the filter has sufficiently large openings to allow a majority of micro organisms to pass through unharmed.

Therefore, the method for reducing obstructions in the annulus of an LNG heat exchangers comprises the steps of periodically flushing the annulus of the heat exchanger with a solution containing a biocide and scaling and corrosion inhibitors and allowing the annulus to recover and dry prior to reactivating the operation of a heat exchanger. These and other advantageous features of the present invention will be in part apparent and in part pointed out herein below.

### BRIEF DESCRIPTION OF THE DRAWINGS

For a better understanding of the present invention, reference may be made to the accompanying drawings in which:

FIG. 1 is an illustration of LNG receiving terminal including a heat exchanger and salt cavern;

FIG. 2(A) is an illustration of an enlarged section of the heat exchanger and communication with the warmant reservoirs;

FIG. 2(B) is an illustration of 2(A) with a counterflow arrangement.

FIG. 3 is an illustration of an offshore receiving terminal including an heat exchanger, warmant reservoir and salt cavern; and

FIG. 4 is a cross-sectional view of the annulus area of a heat exchanger.

### DETAILED DESCRIPTION OF INVENTION

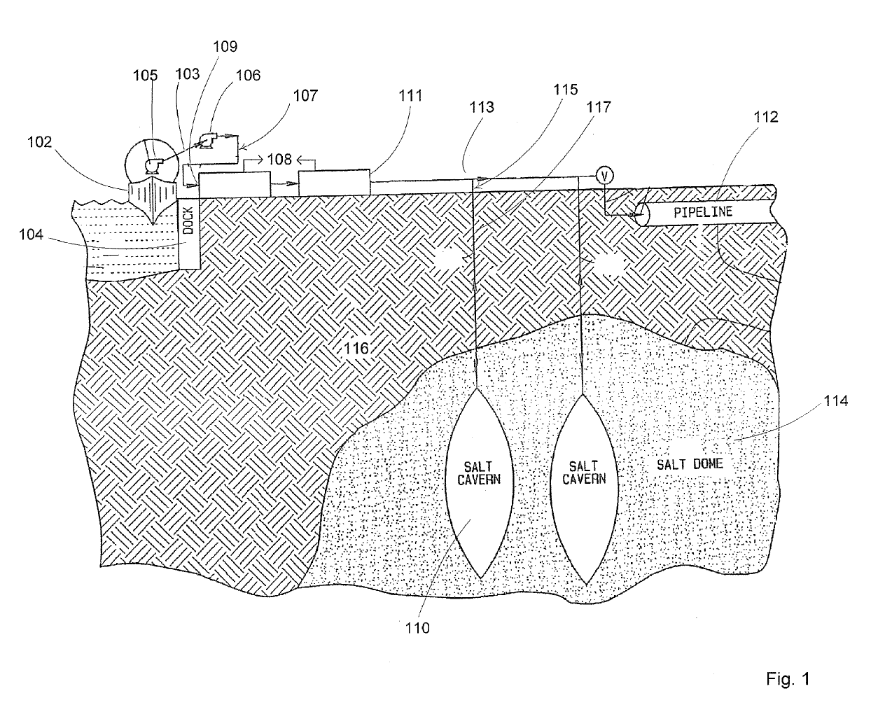

According to the embodiment(s) of the present invention, various views are illustrated in FIG. 1-3 and like reference numerals are being used consistently throughout to refer to like and corresponding parts of the invention for all of the various views and figures of the drawing. Also, please note that the first digit(s) of the reference number for a given item or part of the invention should correspond to the FIG. number in which the item or part is first identified.

One embodiment of the present invention comprising an LNG receiving terminal having a heat exchanger operable to flush and recover teaches a novel apparatus and method for maintaining heat exchanger systems of LNG receiving terminals.

The details of the invention and various embodiments can be better understood by referring to the figures of the drawing. Referring to FIG. 1, an illustration of an LNG transport ship receiving terminal heat exchange and storage is shown. FIG. 1 illustrates an LNG transport ship 102 embarked at a dock 104 for offloading the LNG carried thereon.

An articulated piping system is connected to the low pressure pump system 105 on the transport ship. The other end of the articulated piping is connected to a high pressure pump system 106. The low pressure pump system and the high pressure pump system transfer the cold fluid from the cryogenic tank of the transport ship through piping 107 and inlet 109 of the heat exchanger 108. When the cold fluid leaves the high pressure pump it can be converted to a dense phase fluid because of the pressure imported by the pump. The heat exchanger warms the cold fluid to about +40 degrees Fahrenheit or higher. When the cold fluid leaves the outlet 111 of the heat exchanger it is a dense phase fluid. Piping 113 connects the outlet of the heat exchanger with a well head 115 mounted on well 117 leading to a salt cavern 100. Dense phase fluid is thereby stored in a salt cavern. The present invention uses an impeller to affect flow of the warmant liquid, i.e., seawater or fresh water, which preferably has low speed pump impellers to minimize biota destruction. The present invention also preferably uses a heat exchanger that has a filtration system having filters with the maximum possible filter screen opening size such that the biota flowing there through will likely survive.

A pumping system 106 is shown for pumping the LNG through the heat exchange system 108 which is communicably linked to a salt cavern 110. The salt caverns or storage containers or communicably linked to a pipeline network 112 for delivering natural gas to the market. The salt cavern is formed in a salt dome 114 which is located beneath the earth 116.

The pumping system includes a low pressure pump system and a high pressure pump system for transferring new material from the cryogenic tanks onboard the transport ship through hoses and onto the high pressure pump system. The high pressure pump system raises the pressure of the LNG. When the pressure is raised to a sufficient level, the LNG is converted to a dense phase fluid. The dense phase fluid is then pumped through the heat exchanger for warming. The dense phase fluid exits the heat exchanger at approximately 40 degrees Fahrenheit and is channeled to and stored in the salt cavern.

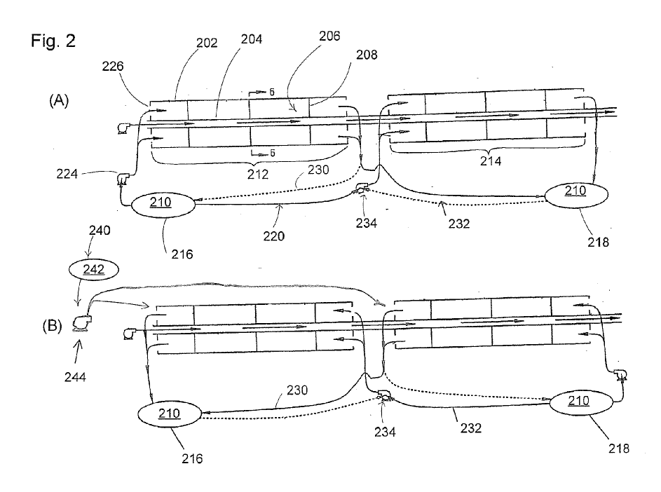

Referring to FIG. 2, an enlarged section of the heat exchanger is shown. The heat exchanger comprises an inner conduit 204 capable of transporting cryogenic materials and further includes an outer coaxial conduit shell 202 where the inner conduit and the outer conduit have an annulus space 206 there between. The interior cryogenically compatible conduit is positioned at or near the center of the outer conduit by a plurality of centralizers 208. A warmant 210 such as sea water flows through the annulus area of the heat exchanger.

The heat exchanger illustrated in FIG. 2 includes a first section 212 and a second section 214. Each of the first and second sections include a central cryogenically compatible conduit and an outer conduit. FIG. 2 also illustrates two reservoirs 216 and 218 for storing warmant such as sea water or fresh water. However, use of a reservoir is not necessary. The warmant may be taken from and returned to a warmant source such as an ocean, lake, or other body of water. Piping 220 and 222 connects the reservoir to a low pressure pump and additional piping connects the low pressure pump 224 with a port 226 to allow fluid communication between the warmant source and the first section of the heat exchanger. The low speed impellers cause the warmant to flow through the annulus area as indicated by the flow areas and exits the first section of the heat exchanger. The warmant flows through the annulus area of the second section in a similar manner. The warmant continues to flow through the annulus area during transfer or offloading of the LNG from the transport ship. Once the transfer into the salt caverns is completed the warmant pumping is discontinued and the remaining warmant is allowed to drain off.

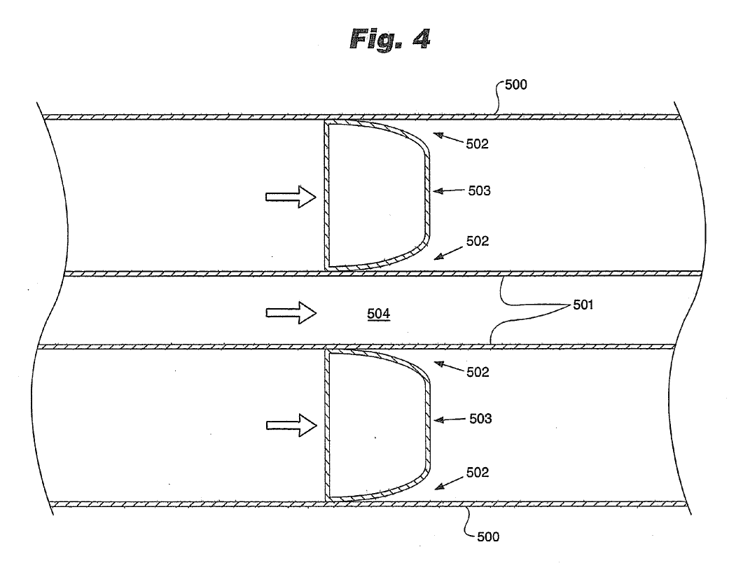

FIG. 4 shows a cross section of the exchanger annulus area. The flow in this area consists of a low velocity zone 502 near the cryogenic pipe wall 501 and at the warmant pipe wall 500, with a turbulent flow region 503 in the center. The biota flowing along this annulus will necessarily have close to neutral buoyancy because of where they must exist in the sea or other body of water, just below the surface. They are also more rigid than the fluid around them and are forced to follow the path of least resistance, which caries them to the turbulent center zone of the flow. This is similar to chips thrown into a stream where they immediately move to the central part of the stream. This flow path keeps the biota away form the shear zones at the walls as well as away from the very cold cryogenic wall 501 and prevents them from freezing. The shear levels the biota experience in this environment is roughly 30 times lower than that shown to cause kills. Total temperature drop along the heat exchanger is only about 12 degrees F. and this also is within the normal temperature range of the biota. The fluid velocity in the annulus is about the same as in a smooth flowing river and it is expected also that the turbulence levels are similar, similar also to that produced by ocean waves. Thus negligible damage is expected to the biota, either from temperature or turbulence as they traverse the length of the exchanger.

This process may cause scaling, corrosion and the forming of biofilm. One embodiment of the present invention entails performing a periodic flush and recover of the annulus utilizing a flush solution containing a biocide and inhibitors for corrosion and scaling. The present invention also utilizes low speed pump impellers for pumping warmant from the warmant source to minimize biota destruction.

FIG. 2A reflects a parallel flow configuration for the heat exchanger which transfers warmant 210 from the first reservoir 216 through the first section 212 to the second reservoir 218. Likewise, additional warmant is transferred from the first reservoir 216 through the second section 214 of the heat exchanger to the second reservoir 218. Over time, the volume of the warmant 210 in the first reservoir will be diminished and the volume of the warmant in the second reservoir will be increased. It will therefore be necessary to move to a counterflow arrangement shown in FIG. 2B so that the warmant can be transferred from the second reservoir 218 back to the first reservoir 216. In an alternative arrangement that avoids the necessity for counterflow, the warmant 210 can be returned from the first section 212 through piping 230 shown in phantom lines to the first reservoir 21 6 allowing for continuous parallel flow through the first section of the heat exchanger. In a similar arrangement, the warmant from the second section 214 can be transferred from a second reservoir 218 through piping 232 shown in phantom lines to pump 234.

As part of the present invention, the heat exchange system is also in fluid communication with a flushing reservoir 240 where the flushing reservoir contains a solution having a biocide element as well as elements for inhibiting scale buildup and corrosion. The biocide solution 242 can be pumped through the heat exchange annulus by a pump 244 thereby flushing the annulus with a solution that prevents biofilm buildup, scale buildup and corrosion. Once the annulus has been flushed by the solution, the annulus is allowed to drain prior to performing the next transfer ship offload operation. The heat exchanger must be designed such that easy drainage occurs. Alternately, the flush can be forced from the exchanger using air or other medium. The use of a periodic flush and recovery to clean the annulus, rather than the conventional constant biocide injection, virtually eliminates biota kills due to the biocide.

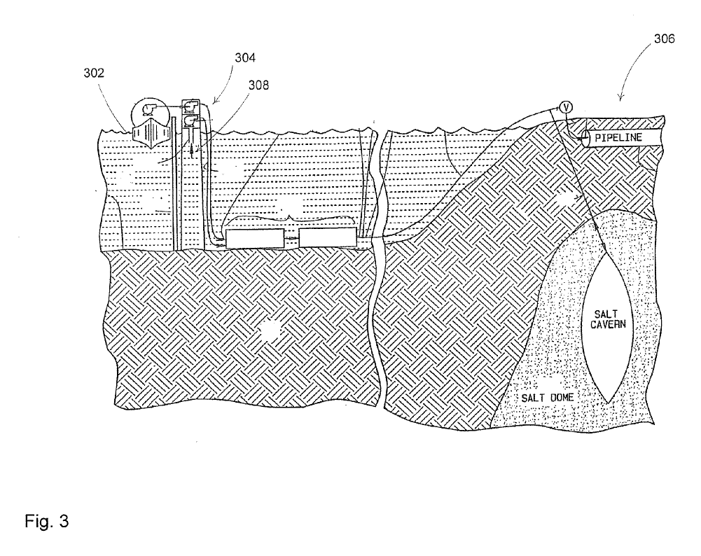

Referring to FIG. 3, an illustration of an LNG receiving terminal having a reservoir is shown. FIG. 3 illustrates the receiving terminal where the ship 302 is moored off shore. The receiving facility 304 is located offshore and the storage facility 306 is located on shore. FIG. 3 reflects an alternative sub sea heat exchanger configuration. This configuration also reflects an off shore warmant reservoir 308. With this configuration, an off shore flush reservoir must also be provided with the appropriate pumping systems.

The various embodiments shown above illustrate a novel method for reducing biofilms, scaling, and corrosion and reducing negative impact of heat exchanger water handling. A user of the present invention may choose any of the above embodiments, or an equivalent thereof, depending upon the desired application. In this regard, it is recognized that various forms of the subject invention could be utilized without departing from the spirit and scope of the present invention.

As is evident from the foregoing description, certain aspects of the present invention are not limited by the particular details of the examples illustrated herein, and it is therefore contemplated that other modifications and applications, or equivalents thereof, will occur to those skilled in the art. For example, the above outlined methods and systems can be applicable to similar or like heat exchanger systems that utilize a fluid warmant method and the method is in no way limited to only LNG heat exchanger systems. The present invention is particularly applicable to heat exchange systems utilizing sea water as the warmant, due to the possible bio film, scale and corrosion problems. The method is also applicable for systems that attempt to minimize the environmental impact of treating water handling equipment to control fouling, scaling and corrosion.

Heat exchangers, cooling towers, hydrocarbon wells, etc. can add biocides and scale and corrosion inhibitors to the water used to perform the required function of cooling, warming, etc. The method proposed here uses a periodic flush procedure which recovers the flush and reuses it. When the flush is depleted or otherwise loses its function, the flush is disposed of consistent with environmental regulations. The specific example outlined above is the use of sea water to warm LNG for injection into a pipeline or into a salt cavern.

One type of heat exchanger that used to do this is the Bishop Process™ Heat Exchanger which operates intermittently, that is when a tanker is offloading. When the tanker is away it is proposed to flush the exchanger with a solution containing biocides and scale and corrosion inhibitors. After the flush, the exchangers are drained and the flush is returned to its storage tank. When the flush, after many uses, is depleted it is disposed of.

There are multiple types of heat exchangers such as open rack, shell and tube, flat plate, standard pipe-in-pipe (LNG and non-LNG), cooling towers, etc. as needed. There are other systems that move water but are not heat exchangers, say an irrigation system that gets bio-fouled or a fresh water injection system for cavern leaching. All of these could benefit from the present inventions flushing process.

Other types of heat exchangers, such as Open Rack Vaporizers, may not operate intermittently as they are a demand type of exchanger. In this case individual units of the exchangers would be shut down and flushed one at a time. Experience with “dosing” where the active material is injected into a continuously flowing stream periodically, indicates that periodic flushing will be effective. It is accordingly intended that the claims shall cover all such modifications and applications that do not depart from the spirit and scope of the present invention.

Other aspects, objects and advantages of the present invention can be obtained from a study of the drawings, the disclosure and the appended claims.

What is claimed is:

1. A method for minimizing warmant blockage in a heat exchanger utilizing a circulating warmant comprising:
a. removing substantially all of said warmant from said heat exchanger;
b. flushing said heat exchanger with a flush solution comprising a cleansing agent selected from the group consisting of a biocide, a scale inhibitor, a corrosion inhibitor and combinations thereof; and
c. removing said flush solution from said heat exchanger.
